(19) United States
(12) Patent Application Publication
(10) Pub. No.: US 2007/0298546 A1
(43) Pub. Date: Dec. 27, 2007

(54) Manufacturing method package substrate

(75) Inventors: Jong-Jin Lee, Daejeon (KR); Sun-Moon Kim, Daejeon (KR); Mi-Seon Shin, Cheongiu-si (KR); Yong-Bin Lee, Cheongiu-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/785,093

(22) Filed: Apr. 13, 2007

(30) Foreign Application Priority Data
Jun. 21, 2006 (KR) 10-2006-0055833

(51) Int. Cl. H01L 21/00; H01L 21/44

(52) U.S. Cl. 438/124; 438/613; 257/E23.02

(57) ABSTRACT

A manufacturing method of a package substrate is disclosed. The method for manufacturing a package substrate is by forming a bump on a bump pad in a core board, where a first circuit pattern including the bump pad is formed on one surface, a second circuit pattern electrically connected with the first circuit pattern is formed on the other surface, and a dielectric layer is selectively coated on the one surface such that the bump pad is exposed. The method includes layering a conductive layer on the other surface of the core board, coating a plating resist on the conductive layer, forming the bump by supplying electricity to the conductive layer to electroplate the bump pad, and removing the plating resist and the conductive layer. This makes it possible to omit the coining process and increase the density of the circuit by forming a fine bump by an electro tin plating method with small plating thickness deviation without designing additional plating bus lines, and improves the electrical performance without remaining plating bus lines.

### CROSS-REFERENCE TO RELATED APPLICATIONS

This application claims the benefit of Korean Patent Application No. 10-2006-0055833 filed with the Korean Intellectual Property Office on Jun. 21, 2006, the disclosure of which is incorporated herein by reference in its entirety.

### BACKGROUND

1. Technical Field

The present invention relates to a manufacturing method of a package substrate.

2. Description of the Related Art

A package substrate is a printed circuit board such as an FCP-(Flip chip package), CSP (Chip scale package), and BGA (Ball grid array) used in an electronic package where electronic chips are mounted, and the pitch, precision, reliability, and cost, etc., of electric contact points between a package substrate and an electronic chip mounted on its surface are very important factors which determine the performance of the package.

In the manufacturing process of a package substrate according to prior art, solder resist is first spread on the surface of a substrate, after which a solder mask coating layer is formed by selective exposure and development and then drying. Next, the bump pads and solder ball pads exposed to the surface of the substrate are plated with gold by electroless plating, and after a process of printing solder paste using a fixture such as a metal mask, the reflow and deflux processes are performed where the printed solder paste is melted in a high temperature and the flux is removed.

Next, in order to make the height of bumps uniform, the coining process is performed, in which the peaks of the bumps are flattened, and the packaging process is performed, in which an electronic chip is mounted, to complete the manufacturing of the package.

Using a Flip Chip Package Substrate as an example, electroless gold (Au) plating is used as a surface treatment technology as described above, and solder printing is applied as a pre-solder technology, where bumps are formed before the solder balls. As other surface treatment technologies, OSP (Organic Solderability Preservatives) treatment technology, Immersion Sn Plating technology, etc., are being applied, in which a copper layer is protected by organic membrane treatment to prevent the oxidation of the copper layer.

After applying the surface treatment technologies as above, solder printing is usually applied, in order to form a bump for electrical connection with a flip chip mounted on the package substrate. In solder printing, it is difficult to form bumps with uniform height and width, and thus an additional process such as coining is necessary in order to make the heights of the bumps uniform. Also, inferiorities such as missing bumps may occur, depending on the quality of the surface treatment, and it is difficult to realize fine pitches, due to the inability to obtain bump pitches below a certain dimension.

In order to resolve these faults, electro tin plating may be applied as a wafer bumping technology. However, in order to apply electroplating to a package substrate, plating bus lines need to be included in the substrate design, whereby the circuit density is lowered, and the manufacturing of high-density circuit products becomes difficult. After the electroplating has been completed, plating bus lines are cut by a router or by dicing, and in this process some plating bus lines may not be completely severed, to cause noises in the transmission of electrical signals due to the plating bus lines remaining on the package substrate. This consequently deteriorates the electrical performance of the product.

### SUMMARY

An aspect of the invention is to provide a manufacturing method of a package substrate which enables fine pitch of bumps for electrical connection with an electronic chip on a package substrate and allows uniform widths and heights, to lessen the defect rate of the bumps, and to realize high-density packages.

One aspect of the invention provides a method for manufacturing a package substrate by forming a bump on a bump pad in a core board where a first circuit pattern including the bump pad is formed on one surface, a second circuit pattern electrically connected with the first circuit pattern is formed on the other surface, and a dielectric layer is selectively coated on the one surface such that the bump pad is exposed. The method includes layering a conductive layer on the other surface of the core board, coating a plating resist on the conductive layer, forming the bump by supplying electricity to the conductive layer to electroplate the bump pad, and removing the plating resist and the conductive layer.

An electroless plated layer including tin (Sn) may be coated on a surface of the bump pad. The electroplated layer and the electroless plated layer may include one or more selected from a group consisting of gold (Au), tin (Sn), Sn—Pb alloys, Sn—Ag alloys, Sn—Cu alloys, Sn—Zn alloys, and Sn—Bi alloys.

The second circuit pattern may include a solder ball pad, and a dielectric layer may be selectively coated on the other surface of the core board such that the solder ball pad is exposed, while the method may further include joining a solder ball on the solder ball pad, and mounting an electronic chip on one surface of the core board such that the electronic chip is electrically connected with the bump, after the removing.

The dielectric layer may be formed by spreading solder resist on one surface of the core board, and removing the solder resist selectively by exposure and development in correspondence with the location of the bump pad.

The layering may include layering a copper (Cu) layer by vacuum plating. The coating may comprise laminating a dry film on the copper layer.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow chart illustrating a manufacturing method of a package substrate according to an embodiment of the present invention.

FIG. 2 is a schematic diagram illustrating a manufacturing process of a package substrate according to an embodiment of the present invention.

FIG. 3 is a sectional view illustrating a package substrate according to an embodiment of the present invention.

FIG. 4 is a sectional view illustrating the pitch of bumps of a package substrate according to a first disclosed embodiment of the present invention, compared with that of prior art.

FIG. 5 is a sectional view illustrating the pitch of bumps of a package substrate according to a second disclosed embodiment of the present invention, compared with that of prior art.

FIG. 6 is a sectional view illustrating the height deviation of bumps of a package substrate according to an embodiment of the invention, compared with that of prior art.

FIG. 7 is a plan view illustrating the pitch of bumps of a package substrate according to an embodiment of the invention, compared with that of prior art.

### DETAILED DESCRIPTION

The manufacturing method of package substrate according to certain embodiments of the invention will be described below in more detail with reference to the accompanying drawings, in which those components are rendered the same reference number that are the same or are in correspondence, regardless of the figure number, and redundant explanations are omitted.

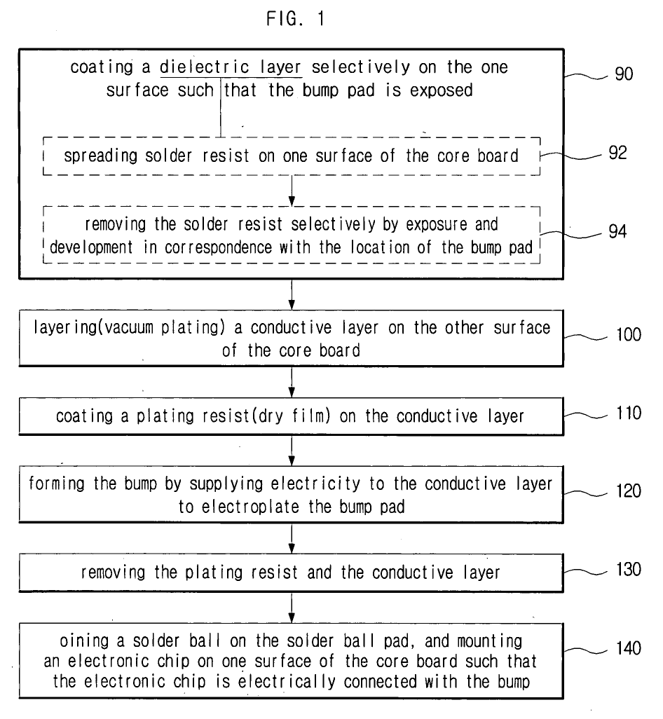

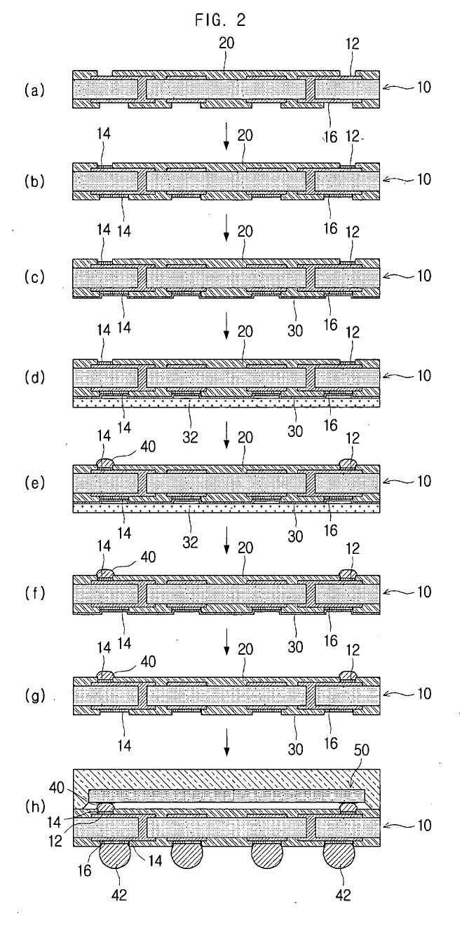

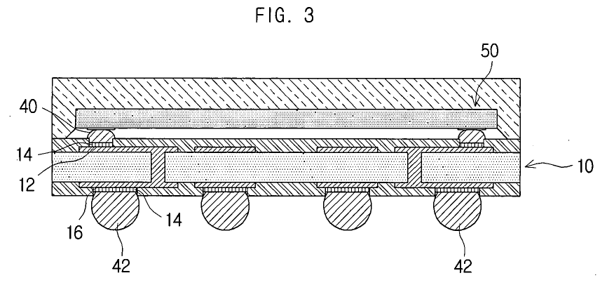

FIG. 1 is a flow chart illustrating a manufacturing method of a package substrate according to an embodiment of the present invention, FIG. 2 is a schematic diagram illustrating a manufacturing process of a package substrate according to an embodiment of the present invention, and FIG. 3 is a sectional view illustrating a package substrate according to an embodiment of the present invention. Referring to FIG. 2 and FIG. 3, a core board 10, bump pads 12, electroless plated layers 14, solder ball pads 16, solder masks 20, a conductive layer 30, a plating resist 32, bumps 40, solder balls 42, and an electronic chip 50 are illustrated.

The present embodiment is a method of manufacturing a package substrate by forming the bumps 40 on the core board 10 where the bump pads 12 are exposed on one surface, in which circuit patterns are formed on both sides of the core board 10 that are connected electrically with each other. The electrical connection between circuit patterns can be realized through via holes, etc. For the core board 10 of the present embodiment, printed circuit boards may be used that have not only 2 layers of circuit patterns on both sides, but also with multiple layers of circuit patterns.

The bump pads 12, to which the bumps 40 are to be joined, are included as a part of the circuit pattern formed on one surface of the core board 10, and the solder ball pads 16, to which the solder balls 42 are to be joined, are included as a part of the circuit pattern formed on the other surface of the core board 10. The bump pads 12 are exposed at one surface of the core board 10, and this is realized by coating the solder mask 20 on one surface of the core board 10 where the circuit pattern including the bump pads 12 is formed, and by selective coating such that only opens the bump pad 12 portions (90).

That is, as in FIG. 2 (a), by spreading solder resist on one surface of the core board 10 (92), and removing the solder resist in the portions where the bump pads 12 are formed by selective exposure and development, the solder mask 20 is selectively coated (94).

On the other surface of the core board 10, the solder ball pads 16 where the solder balls 42 are to be joined are exposed, and this is realized by selective coating of the solder mask on the other surface of the core board 10 just as for exposing the bump pads 12.

On the bump pads 12 exposed at one surface of the core board 10 and on the surfaces of the solder ball pads 16 exposed at the other surface, immersion Sn plating is performed such that the electroless plated layer 14 is coated, in order to obtain a smooth connection with the bumps 40 and the solder balls 42, as in FIG. 2 (b). As the material of the electroless plated layer 14, not only tin (Sn) but also tin alloys such as Sn—Pb alloys, Sn—Ag alloys, Sn—Cu alloys, Sn—Zn alloys, and Sn—Bi alloys, etc. may also be used.

After forming the electroless plated layer 14 on the bump pads 12 and solder ball pads 16, in order to electroplate on the bump pad 12, the conductive layer 30 is layered as in FIG. 2 (c) on another surface of the core board 10, that is, on the side where the solder ball pads 16 are exposed (100). On both sides of the core board 10, circuit patterns are formed that are electrically connected with each other, the bump pads 12 included as a part of the circuit pattern are exposed at one surface of the core board 10, and the solder ball pads 16 are exposed on another surface of the core board 10 as a part of the circuit pattern. Thus, by supplying electricity to the conductive layer 30 layered on another surface of the core board 10, the bump pads 12 can be connected electrically.

Therefore, the conductive layer 30 of the present embodiment plays the same role as the plating bus line of prior art. In the present embodiment, without additional plating bus line design, the conductive layer 30 is layered on the surface opposite to the surface where the bump pads 12 are formed in the process of manufacturing a package substrate, and removed after plating, so that the pitch of the bump pads 12 does not increase due to the designing of plating bus lines, and the electrical performance of the package does not deteriorate due to the remaining of the plating bus lines.

Since the conductive layer 30 is only layered on one surface of a substrate, that is the surface opposite to the surface where the bump pads 12 are formed, it is desirable to form an electrical conductive layer such as by copper (Cu), etc. (100), by applying a directional vacuum plating method such as by sputtering, ion beams, etc., as the method of forming the conductive layer 30.

Next, as in FIG. 2 (d), the plating resist 32 is coated by spreading liquid plating resist 32 on the conductive layer 30 or laminating a dry film (110). This is for preventing the plated layer from layering on a surface of the conductive layer 30 in the process of electroplating the bump pad 12 by supplying electricity to the conductive layer 30.

Next, as in FIG. 2 (e), by supplying electricity to the conductive layer 30 and layering an electroplated layer on the bump pad 12, the bumps 40 are formed for electrically connecting the package substrate and the electronic chip 50 (120). As the material of the electroplated layer, gold (Au), tin (Sn), Sn—Pb alloys, Sn—Ag alloys, Sn—Cu alloys, Sn—Zn alloys, and Sn—Bi alloys, etc. may be used.

After forming the bumps 40 on the bump pads 12 by electroplating, the plating resist 32 is stripped off as in FIG. 2 (f), and the conductive layer 30 coated on another surface of the core board 10 that serves as the plating bus lines is removed by etching, etc. (130) as in FIG. 2 (g).

In this manner, after forming the bumps 40 on the bump pads 12, and joining the solder balls 42 with the solder ball pads 16 exposed at another surface of the core board 10, and lastly mounting the electronic chip 50 on one surface of the core board 10 as in FIG. 2 (h), the electronic chip 50 is electrically connected with the bumps 40, to manufacture an electronic package (140).

The structure of a package substrate manufactured in this method is as shown in FIG. 3, a characteristic of which is that the bumps 40 are formed by electroplating without additional plating bus line design in forming the bumps of a flip chip package substrate such as an FCBGA (Flip Chip Ball Grid Array), and FCCSP (Flip Chip Scale Package), etc., and that the surfaces of the bump pads 12 and the solder ball pads 16 of the flip chip package substrate are treated by electroless tin plating, and the bumps 40 are formed on the electroless plated layer 14 by electro tin plating.

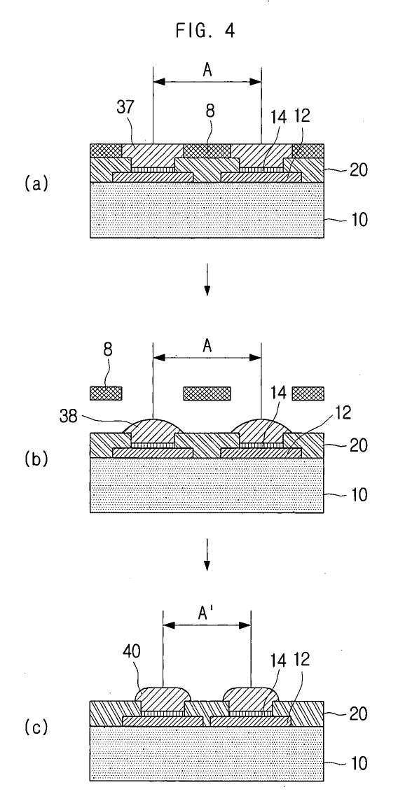

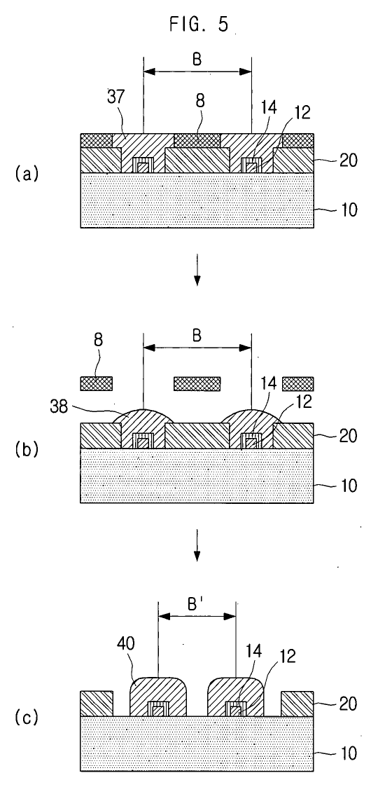

FIG. 4 is a sectional view illustrating the pitch of bumps of a first disclosed embodiment of a package substrate compared with that of prior art, and FIG. 5 is a sectional view illustrating the pitch of bumps of a second disclosed embodiment of a package substrate compared with that of prior art. Referring to FIG. 4 and FIG. 5, a metal mask 8, a core board 10, bump pads 12, electroless plated layers 14, a solder mask 20, solder paste 37, and bump 38, 40 are illustrated.

FIG. 4 illustrates, in an SMD (solder mask define) type where the width of a bump is defined by the solder mask 20, the pitch of the bumps 38 of the case of prior art, where the metal mask 8 is used as in FIGS. 4 (a), (b), compared with the case of applying the present embodiment, as in FIG. 4 (c).

In the case of prior art, after coating the solder mask 20 on a surface of the core board 10 where a circuit pattern including the bump pads 12 is formed, and laminating the metal mask 8 where the bump pads 12 portion is opened selectively, the solder paste 37 is filled in the opened portions of the metal mask 8 as in FIG. 4 (a), and the bumps 38 are formed by removing the metal mask 8 as in FIG. 4 (b). Therefore, the pitch of the bumps 38 (‘A’ of FIGS. 4 (a), (b)) depends on the precision of the metal mask 8.

In the solder printing method of this SMD type, not only are there manufacturing errors of the metal mask 8, but there are also aligning errors in the process of aligning the opened portions of the metal mask 8 with the bump pads 12 of the core board 10, and it is difficult to form the bumps in a fine pitch under a certain gap due to the spreading of the solder paste 37 during the coining process.

On the other hand, in the present embodiment, since electro tin plating is applied directly to the bump pads 12 exposed at a surface of the core board 10 without an additional metal mask 8 in SMD type as in FIG. 4 (c), the bumps 40 (“A” of FIG. 4 (c)) are realized with a finer pitch than those obtained from a conventional solder printing method.

FIG. 5 illustrates, an NSMD (non-solder mask define) type where the width of a bump is not defined by the solder mask 20, and the bumps 38 are filled in after forming solder mask dams, comparing the pitch of the bumps 38 of the case of prior art where the metal mask 8 is used as in FIG. 5 (a), (b) with the case of applying the present embodiment as shown in FIG. 5 (c).

In the case of prior art, after coating the solder mask 20 dams between the bump pads 12 on the core board 10 where a circuit pattern including the bump pads 12 is formed, and laminating the metal mask 8 where the bump pad 12 portions are opened selectively, the solder paste 37 is filled in the opening of the metal mask 8 as in FIG. 5 (a), and the bumps 38 are formed by removing the metal mask 8 as in FIG. 5 (b). Therefore, the pitch of the bumps 38 (‘B’ of FIG. 5 (a), (b)) depends on the solder mask 20 dams and the pitch of the metal mask 8.

In the solder printing method of this NSMD type, the opened portions of the metal mask 8 should be aligned with the bump pads 12 of the core board 10 just as in the SMD type, and it is difficult to form bumps of a fine pitch under a certain gap due to the spreading of the solder paste 37 during the coining process.

Here, in order to form bumps on the bump pads 12 directly without forming the solder mask 20 dams to make the pitch of bumps fine, special solder paste 37 such as ‘Super Juffit’, ‘Super Solder’ is used, which is expensive in cost.

On the other hand, in the present embodiment, electro tin plating is applied directly to the bump pads 12 exposed at a surface of the core board 10 without an additional metal mask 8 in the NSMD type as shown in FIG. 5 (c), so that bumps 40 (“B” of FIG. 5 (c)) of a finer pitch than those of a conventional solder printing method may be realized. Also, in the present embodiment where electro tin plating method is applied, it is possible to form the bumps 40 without forming the solder mask 20 dams between the bump pads 12, so it is more beneficial in realizing fine bump pitch.

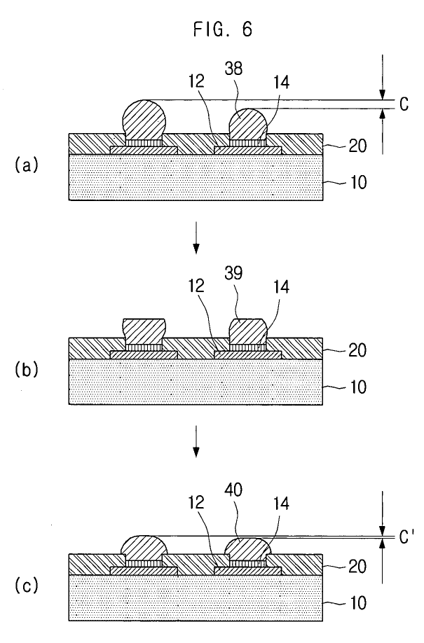

FIG. 6 is a sectional view illustrating the height deviation of bumps of an embodiment of a package substrate compared with that of prior art. Referring to FIG. 6, a core board 10, bump pads 12, electroless plated layers 14, a solder mask 20, and bumps 38, 39, 40 are illustrated.

FIG. 6 illustrates the height deviation (‘C’ of FIG. 6 (a)) of the bumps 38 formed by a conventional solder printing method, the state (FIG. 6 (b)) after applying a coining process to decrease the deviation, and in comparison, the height deviation (“C” of FIG. 6 (c)) of the bumps 38 formed by applying the present embodiment.

Because a fixture such as a metal mask 8 is used to form the bumps 38 by a conventional solder printing method, it is difficult to keep the amount of the solder paste 37 filled in the open portions of the metal mask 8 uniform, so that the height deviation of the bumps 3.8 formed is great, as in FIG. 6 (a). To improve this, the surfaces of the bumps 39 are flattened by additionally applying a flattening process named coining, as shown in FIG. 6 (b).

On the other hand, in the case of forming the bumps 40 by applying an electro tin plating method as in the present embodiment, the deviation of plating thickness is small, so that the height deviation of the bumps 40 is not great, as in FIG. 6 (c), and the additional flattening process such as coining is unnecessary.

Moreover, in a conventional solder printing method, in the case where the amount of the filled solder paste 37 is absolutely insufficient, it is hard to acquire the minimum amount of flat surfaces for bump connection with the electronic chip 50 even with coining, and in the case where the state of the surface of the bump pad 12 is not good, faults may occur such as missing bumps. On the other hand, by forming the bumps 40 by applying electro tin plating method as in the present embodiment, these faults in the bumps can be minimized.

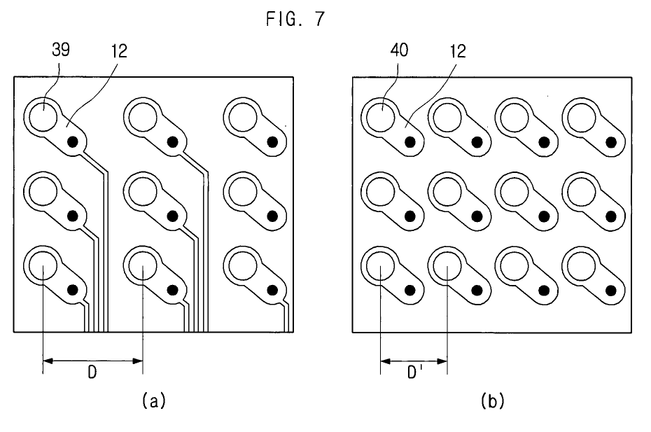

FIG. 7 is a plan view illustrating the pitch of bumps of an embodiment of a package substrate compared with that of prior art. Referring to FIG. 7, bump pads 12, plating bus lines 31, and bumps 39, 40 are illustrated.

FIG. 7 illustrates the pitch of the bumps 39 in FIG. 7 (a) in the case of designing plating bus lines 31 to manufacture a package substrate by applying an electroplating process according to prior art, and in comparison, the pitch of the bumps 40 in FIG. 7 (b) in the case of manufacturing a package substrate by applying electroplating process according to the present embodiment.

In prior art, in order to apply the electroplating method, which is a wafer bumping technology, to a package substrate, the plating bus line 31 should be inserted in a product as in FIG. 7 (a), when designing the substrate. In this case, the pitch of the bumps 39 (‘D’ of FIG. 7 (a)) increases such that the circuit density decreases, which can be a problem in manufacturing a high density circuit product. Also, in the process of cutting the plating bus lines 31 by a router or by dicing after electroplating, the plating bus lines 31 remaining on the substrate may cause noises in the transmission of electrical signals, to deteriorate the electrical performance of the product.

On the other hand, by forming the bump 40 in electro tin plating method without designing the additional plating bus lines 31 as in the present embodiment, the density of a circuit is increased without increasing the pitch of the bumps 40 (“D” of FIG. 7 (b)), so that it is possible to form bumps of a fine pitch, and there are no plating bus lines 31 remaining, so that electrical performance is improved.

According to certain aspects of the invention as set forth above, by forming fine bumps by the electro tin plating method with small plating thickness deviation without designing additional plating bus lines, the coining process is omitted, the density of the circuit is increased, and there are no plating bus lines remaining, so that electrical performance is improved.

Also, bumps of a fine pitch of under 120 um can be realized with low manufacturing cost, the heights and widths of the bumps are made uniform so that additional flattening process is not needed, and there are fewer faults in the bumps in comparison with those obtained with the conventional solder printing method.

Also, as plating bus lines are not needed, the degree of freedom and flexibility of circuit design are improved, and it is possible to manufacture a high density circuit product. In addition, signal noises caused by remaining plating bus lines for electroplating are prevented, so that the electrical performance of the package substrate is improved.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method for manufacturing a package substrate by forming a bump on a bump pad in a core board where a first circuit pattern including the bump pad is formed on one surface, a second circuit pattern electrically connected with the first circuit pattern is formed on the other surface, and a dielectric layer is selectively coated on the one surface such that the bump pad is exposed, the method comprising:
layering a conductive layer on the other surface of the core board;
coating a plating resist on the conductive layer;
forming the bump by supplying electricity to the conductive layer to electroplate the bump pad; and
removing the plating resist and the conductive layer.

2. The method of claim 1, wherein an electroless plated layer comprising tin (Sn) is coated on a surface of the bump pad.

3. The method of claim 2, wherein the electroplated layer and the electroless plated layer comprise one or more selected from a group consisting of gold (Au), tin (Sn), Sn—Pb alloys, Sn—Ag alloys, Sn—Cu alloys, Sn—Zn alloys, and Sn—Bi alloys.

4. The method of claim 1, wherein the second circuit pattern comprises a solder ball pad, and a dielectric layer is selectively coated on the other surface of the core board such that the solder ball pad is exposed, the method further comprising: joining a solder ball on the solder ball pad, and mounting an electronic chip on one surface of the core board such that the electronic chip is electrically connected with the bump, after the removing.

5. The method of claim 1, wherein the dielectric layer is formed by spreading solder resist on one surface of the core board, and removing the solder resist selectively by exposure and development in correspondence with the location of the bump pad.

6. The method of claim 1, wherein the layering comprises layering a copper (Cu) layer by vacuum plating.

7. The method of claim 6, wherein the coating comprises laminating a dry film on the copper layer.
